(19) United States
(12) Patent Application Publication
(10) Pub. No.: US 2012/0132786 A1
(43) Pub. Date: May 31, 2012

(54) SOLID STATE IMAGING DEVICE

(76) Inventors: Akiko Mori, Yokohama-shi (JP); Satoshi SAKURAI, Kawasaki-shi (JP)

(21) Appl. No.: 13/234,453

(22) Filed: Sep. 16, 2011

(30) Foreign Application Priority Data
Nov. 26, 2010 (JP) 2010-263380

(51) Int. Cl. H01L 27/146

(52) U.S. Cl. 250/208.1

(57) ABSTRACT

According to one embodiment, a solid state imaging device includes a pixel cell including an FD node to convert a charge stored in a photodiode into a signal voltage and an amplifier transistor in which a gate is connected to the FD node, a source is connected to an output signal line, and a drain is connected to a pixel-power node, a voltage control portion including a first control transistor in which a gate sets to a first bias voltage, a source is connected to the output signal line, and a drain is connected to a first control portion-power node, a load circuit including a current source connected directly between one end of the output signal line and a source power supply node, and a control circuit which controls an operation to decide a reset voltage of the output signal line. The control circuit boosts the FD node.

### CROSS-REFERENCE TO RELATED APPLICATIONS

This application is based upon and claims the benefit of priority from prior Japanese Patent Application No. 2010-263380, filed Nov. 26, 2010, the entire contents of which are incorporated herein by reference.

### FIELD

Embodiments described herein relate generally to a solid state imaging device.

### BACKGROUND

A pixel signal reading circuit of a solid state imaging device (for example, a CMOS image sensor) includes pixel cells and a load circuit and has a function to read a charge stored in a photodiode. The charge in the photodiode is transferred to a floating diffusion node (hereinafter, referred to as an FD node) and converted into a signal voltage by a source follower circuit comprising a row select transistor, an amplifier transistor, and the load circuit.

When a pixel signal is read, the FD node is reset to a pixel power supply voltage to discharge the stored charge. Thus, if the pixel power supply voltage drops due to lower power consumption, the reset voltage of the FD node also drops and a reset voltage output from the pixel signal reading circuit drops. As a result, the range of an output voltage of the pixel signal reading circuit becomes narrower so that a sufficient output amplitude cannot be obtained.

To improve the above situation, a technology to increase the output amplitude, to boost the reset voltage using capacity coupling between the output signal line and an FD node, and to expand the range of the output voltage of the pixel signal reading circuit, by temporarily changing the voltage of an output signal line in continuous operations in that a pixel signal is read is known. However, according to this technology, if the load of the load circuit is transiently changed to change the voltage of an output signal line, noise is more likely to be carried on the output signal line.

As a result, a problem of deterioration in image quality is caused.

### BRIEF DESCRIPTION OF THE DRAWINGS

FIG. 1 is a general view of a solid state imaging device;

FIG. 2 is a diagram showing a first embodiment of a pixel signal reading circuit;

FIG. 3 is a timing chart of the circuit in FIG. 2;

FIG. 4 is a diagram showing capacity coupling of floating diffusion;

FIG. 5 is a diagram showing a relationship between an FD voltage and the range of an output amplitude of a source follower;

FIG. 6 is a diagram showing a difference between an original signal component and an output signal component;

FIG. 7 is a diagram showing a second embodiment of the pixel signal reading circuit;

FIG. 8 is a timing chart of the circuit in FIG. 7;

FIG. 9 is a diagram showing a third embodiment of the pixel signal reading circuit; and

FIG. 10 is a timing chart of the circuit in FIG. 9.

### DETAILED DESCRIPTION

In general, according to one embodiment, a solid state imaging device comprising: a pixel cell including an FD node to convert a charge stored in a photodiode into a signal voltage and an amplifier transistor in which a gate is connected to the FD node, a source is connected to an output signal line, and a drain is connected to a pixel-power node; a voltage control portion including a first control transistor in which a gate sets to a first bias voltage, a source is connected to the output signal line, and a drain is connected to a first control portion-power node; a load circuit including a current source connected directly between one end of the output signal line and a source power supply node; and a control circuit which controls an operation to decide a reset voltage of the output signal line, wherein the control circuit boosts the FD node by activating a first source follower circuit comprising the first control transistor and the current source before activating a second source follower circuit comprising the amplifier transistor and the current source, and sets a voltage of the output signal line when the FD node is boosted as the reset voltage.

The embodiments will be described below with reference to drawings.

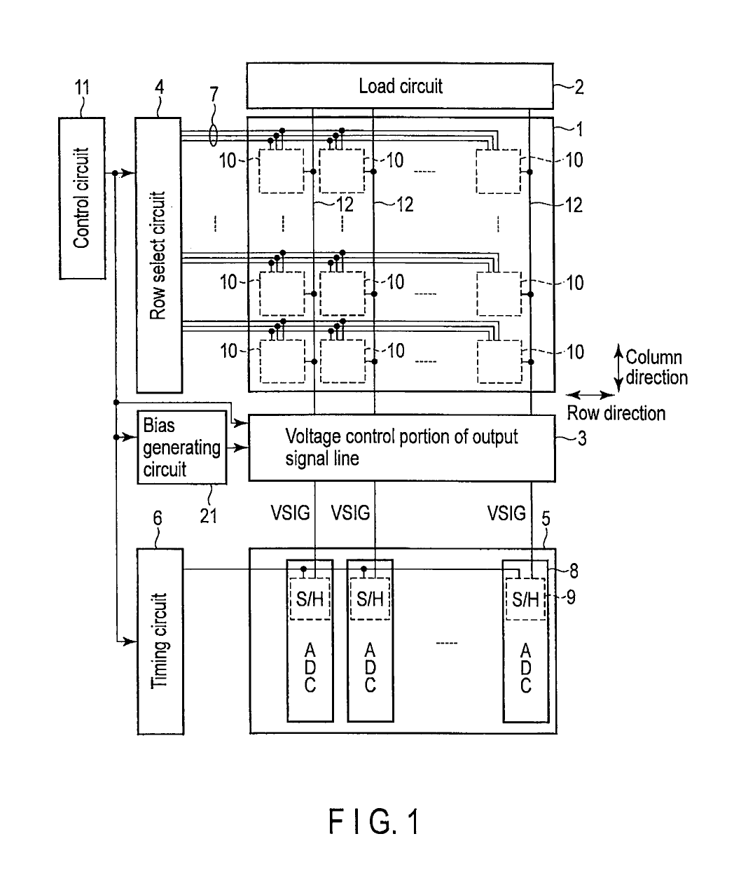

FIG. 1 shows a general view of a solid state imaging device.

Pixel region 1 includes pixel cells 10 arranged like an array. The region other than pixel region 1 is a peripheral circuit region. The peripheral circuit region contains load circuit 2 for reading, voltage control portion 3 to control the voltage of an output signal line, row select circuit 4, AD (Analog-Digital) conversion block 5, timing circuit 6, and bias generating circuit 21. Control circuit 11 controls operations of voltage control portion 3, row select circuit 4, timing circuit 6, and bias generating circuit 21.

Row select circuit 4 uses a control signal line 7 extending in a row direction to select one row (one horizontal line) to be read and also controls reading of a pixel signal from pixel cells 10 in one horizontal line.

If control signal line 7 in one horizontal line is, for example, 4Tr type CMOS image sensor in which four transistors are provided to read one pixel, control signal line 7 contains three signal lines (a row select line, reset control line, and read control line).

For example, one vertical signal line (output signal line) 12 is provided for one column (one vertical line) of a pixel cell array. Voltage control portion 3 controls the voltage of vertical signal line 12. One feature of the present invention is that a source follower circuit is constituted by load circuit 2 and a transistor (FET) inside voltage control portion 3 while reading.

Load circuit 2 includes, as will be described later, no switch function. Load circuit 2 is comprising, for example, only a current source and so will not repeat On/Off in 1H (one horizontal scanning period).

That is, the load of the load circuit does not change transiently when the reset voltage of an FD node is boosted and thus, noise is not carried on vertical signal line 12 and so image quality can be improved.

AD conversion block 5 includes, for example, AD (Analog-Digital) converter 8 containing sample hold (S/H) circuit 9.

Sample hold circuit 9 samples the voltage (reset voltage) of vertical signal line 12 when the reset voltage of an FD node is boosted and holds a sampling result.

Then, a charge stored in the photodiode is transferred to an FD node to read a pixel signal. When the pixel signal is read, the voltage of output signal line 12 also changes due to a change of the voltage of the FD node and the voltage of output signal line 12 at this point becomes a signal voltage. And so sample hold circuit 9 samples the voltage (signal voltage) of vertical signal line 12 when the pixel signal is read and holds a sampling result again.

AD converter 8 containing sample hold circuit 9 calculates a difference between the reset voltage and the signal voltage through sample hold circuit 9 and then performs AD conversion of the difference or performs AD conversion of the reset voltage and the signal voltage separately and then calculates a difference between the reset voltage and the signal voltage in digital value. In both cases, AD converter 8 outputs a difference (signal amount) between the reset voltage and the signal voltage and, as a result, a rise in voltage of vertical signal line 12 when the reset voltage of the FD node is boosted is considered as an offset and canceled. That is, a signal component of a pixel signal can correctly be read (double correlation sampling processing).

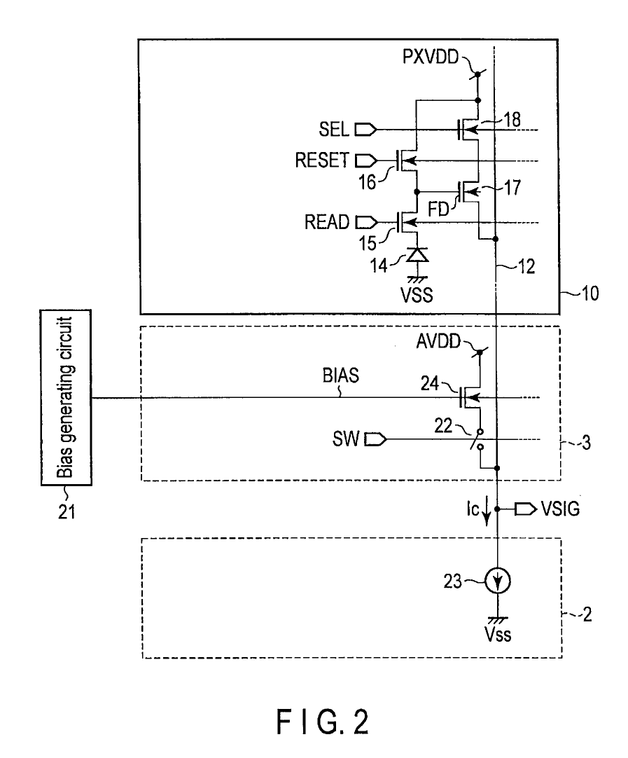

FIG. 2 shows the first embodiment of a pixel signal reading circuit.

The pixel signal reading circuit includes pixel cell 10, load circuit 2, and voltage control portion 3. A row select signal SEL, a reset signal RESET, and a read signal READ are supplied from row select circuit 4 in FIG. 1. Control signal SW is supplied from, for example, control circuit 11 in FIG. 1.

Pixel cell 10 includes photodiode 14, read transistor (FET) 15 to read a charge of photodiode 14 to an FD node, reset transistor (FET) 16 to reset the voltage of the FD node, amplifier transistor (FET) 17 to output the voltage of the FD node, and row select transistor (FET) 18 serving as a switch between a drain of amplifier transistor 17 and pixel-power node PXVDD.

Read transistor 15 is connected to between photodiode 14 and the FD node. A source of the reset transistor is connected to the FD node and the drain thereof is connected to pixel-power node PXVDD to which the pixel power supply voltage is applied.

The source of amplifier transistor 17 is connected to vertical signal line (output signal line) 12. The source of row select transistor 18 is connected to the drain of amplifier transistor 17 and the drain thereof is connected to pixel-power node PXVDD. One vertical signal line 12 is provided for each column (one vertical line) of a pixel cell array and connected to one load circuit 2 at the termination of the pixel cell array, but vertical signal lines may be provided for each vertical line and connected to load circuits.

Load circuit 2 is current source 23.

Current source 23 is directly connected to between one end of vertical signal line 12 and source-power node Vss and thus, load circuit 2 has no switch function.

Voltage control portion 3 includes control transistor (FET) 24 whose gate is connected to bias line BIAS that controls the voltage of an output signal line and switch 22 that controls the connection/disconnection between the source of control transistor 24 and vertical signal line 12. The drain of control transistor 24 is connected to a power node of voltage control portion 3 that controls the voltage of an output signal line, that is, a control portion-power node AVDD.

Switch 22 may be connected to between control portion-power node AVDD and the drain of control transistor 24.

Pixel-power node PXVDD and control portion-power node AVDD may be the same or different. If both are different, voltage Vdd of pixel-power node PXVDD and voltage Vdda of control portion-power node AVDD may be the same or different.

Bias generating circuit 21 supplies a bias voltage to bias line BIAS inside voltage control portion 3.

In the present embodiment, load circuit 2, amplifier transistor 17, and row select transistor 18 constitute a source follower circuit. Further, load circuit 2, switch 22, and control transistor 24 constitute a source follower circuit.

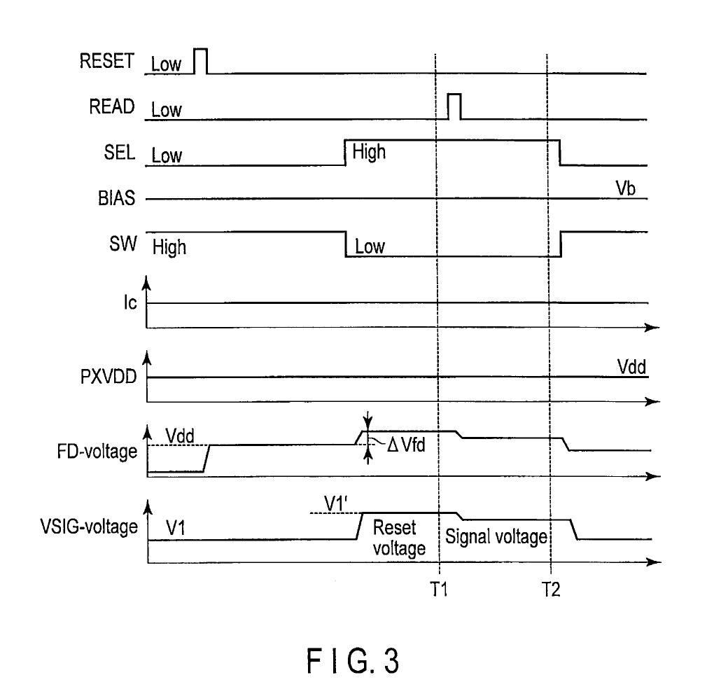

FIG. 3 is a timing chart when a pixel signal of the circuit in FIG. 2 is read.

When a pixel signal is read, switch 22 inside voltage control portion 3 is first turned on while bias circuit 21 supplies bias voltage Vb to bias line BIAS and vertical signal line 12 is set to predetermined voltage value V1. At this point, row select transistor 18 is off and thus, a source follower circuit by load circuit (current source 23) 2, switch 22, and control transistor 24 functions.

Generally, if a substrate bias effect is not taken into consideration, output voltage Vvsig of the source follower circuit is given by Formula (I):

$$Vvsig = Vout = Vin - Vth - \sqrt{\frac{2 Ic}{β}} \\ β = \frac{W}{L} μ \cdot Cox \qquad ( 1 )$$

where Vth is the threshold voltage of a transistor, Ic is the current flowing through the source follower circuit, W and L are the gate width and gate length of the transistor respectively, μ is the mobility of electrons, and Cox is the unit area capacity of a gate oxide film of the transistor.

For Formula (I), it is clear that a value shifted from the voltage applied to a gate terminal of the transistor by a fixed voltage is output as output voltage Vvsig of the source follower circuit and the amount of shift depends on current IC flowing through the source follower circuit, threshold voltage Vth of the transistor, and gate width W and gate length L.

Therefore, voltage V1 of vertical signal line 12 can be represented as follows:

$$V 1 = Vb - Vthb - \sqrt{\frac{2 Ic}{β b}} \\ β b = \frac{W b}{Lb} μ \cdot Cox \qquad ( 2 )$$

where Vb is the bias voltage value generated by bias generating circuit 21, Vthb is the threshold voltage of control transistor 24 inside voltage control portion 3, and Wb and Lb are the gate width and gate length of control transistor 24 inside voltage control portion 3 respectively.

In this state, reset transistor 16 is turned on and off, so the FD node is set to pixel power supply voltage Vdd of pixel-power node PXVDD.

Then, row select transistor 18 inside pixel cell 10 is turned on and switch 22 inside voltage control portion 3 is turned off. At this point, with load circuit 2, amplifier transistor 17, and row select transistor 18, a source follower circuit functions.

Therefore, voltage V1′ of vertical signal line 12 can be represented as follows:

$$V {1}^{′} = Vfd = Vthamp - \sqrt{\frac{2 Ic}{β amp}} \\ β amp = \frac{Wamp}{Lamp} μ \cdot Cox \qquad ( 3 )$$

where Vfd is the voltage of the FD node, Vthamp is the threshold voltage of amplifier transistor 17, and Wamp and Lamp are the gate width and gate length of amplifier transistor 17 respectively.

At this point, Vb, Vthb, Wb, and Lb are set so that V1<V1′ holds.

Then, with a rising voltage of vertical signal line 12 from V1 to V1′, the voltage of the FD node rises by being linked to a rise in output voltage.

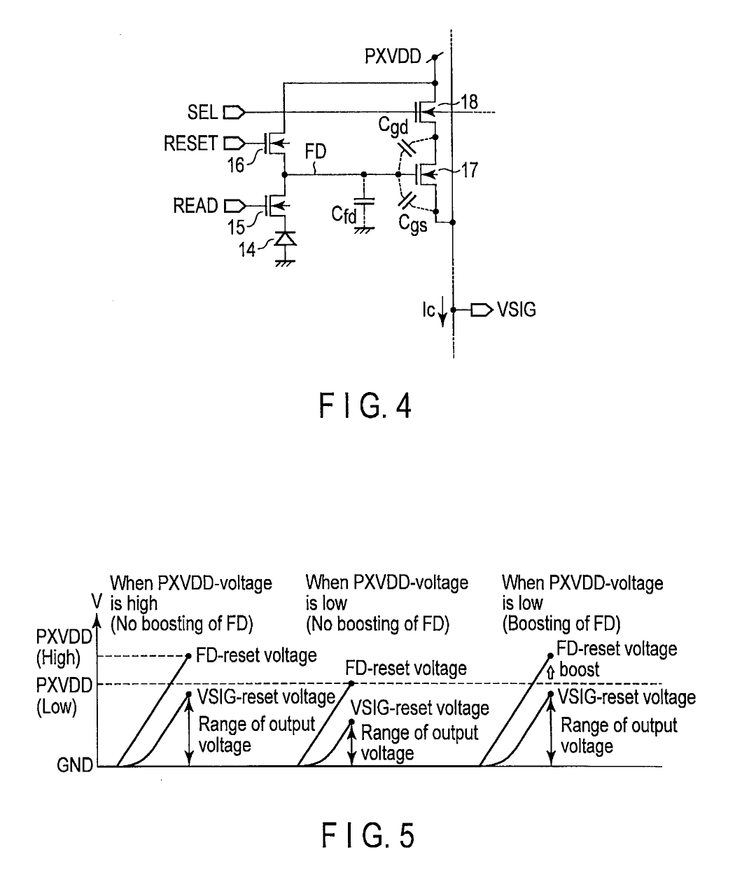

This is because, as shown in FIG. 4, the FD node and vertical signal line 12 are mutually capacity-coupled due to capacity Cgs between the gate and source of amplifier transistor 17.

As shown in Formula (4), an amount of increase ΔVfd in voltage of the FD node is decided by an amount of change ΔVvsig in voltage of vertical signal line 12, coupling capacity values Cgs, Cgd of amplifier transistor 17, and an internal capacity Cfd of the FD node.

$$Δ Vfd = \frac{Cgs}{Cfd + Cgd + Cgs} \times Δ Vvisg \qquad ( 4 )$$

This means that the voltage of the FD node rises in accordance with a rise in voltage of vertical signal line 12. This effect is particularly useful for operation in a low power supply voltage.

As shown in FIG. 5, when an FD node is reset by a reset transistor, the reset voltage of the FD node becomes the voltage of pixel-power node PXVDD. That is, the reset voltage of the FD node has the power supply voltage dependency that the reset voltage drops in accordance with a drop in pixel power supply voltage. If the reset voltage of the FD node drops, the reset voltage output to vertical signal line 12 also drops. This means that the range of the output voltage of a source follower circuit is narrowed.

However, by performing a pixel signal reading operation according to the timing chart in FIG. 3, the FD node can be boosted to increase the reset voltage output to vertical signal line 12. As a result, a wide range of the output voltage can be secured without deterioration in image quality even during operation at low power supply voltage.

The subsequent operation is the same as that for normal pixel signal reading.

First, in timing T1, the output voltage (reset voltage) of vertical signal line 12 is sampled by the sample hold circuit in the subsequent stage. If read transistor 15 is turned on after the reset voltage being sampled, a charge stored in photodiode 14 is transferred to an FD node. The charge is detected by amplifier transistor 17 and also output to vertical signal line 12 as a signal voltage.

In timing T2, the signal voltage is sampled by the sample hold circuit in the subsequent stage. Row select transistor 18 inside pixel cell 10 is turned off after reading of the charge is completed.

The foregoing is a pixel signal reading sequence in the first embodiment.

In the first embodiment, current source 23, which is load circuit 2, continues to pass a constant current during operation of pixel signal reading. Thus, a phenomenon in which a current begins to flow abruptly due to a rise in reset voltage or the like does not occur.

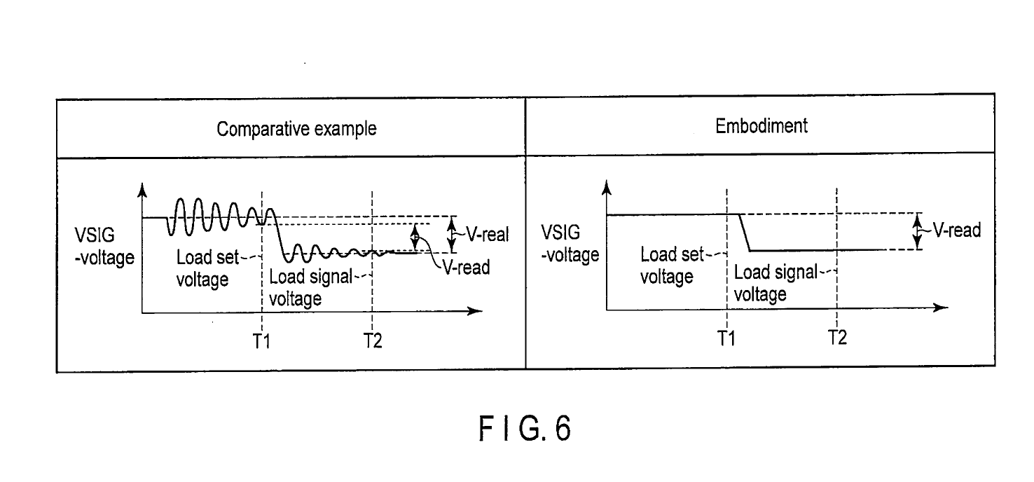

In a comparative example as shown, for example, in FIG. 6, the switch of the load circuit repeats On/Off in 1H and thus, timing in which a current begins to flow into the source follower circuit at a stroke exists and in such a case, voltages of the pixel-power node, FD node, and vertical signal line become very unstable.

Particularly when double correlation sampling processing is performed, voltages are more likely to be subject to instability. If, for example, the reset voltage and signal voltage are sampled when the voltage of the vertical signal line is unstable, a difference arises between an original signal component V-real and an output signal component V-read. The difference is different among vertical signal lines arranged inside a pixel cell array, which becomes a noise component to bring about deterioration in image quality in the end.

In the first embodiment, by contrast, a technology to change the voltage of a vertical signal line without controlling a load circuit is proposed by including only a current source in the load circuit and constituting a source follower circuit by a row select transistor, an amplifier transistor of a pixel cell, and the current source of the load circuit, and by a control transistor of the voltage control portion, a switch, and the current source of the load circuit also.

Accordingly, the reset voltage and signal voltage can be sampled without causing instability of voltages of the pixel-power node, FD node, and vertical signal line. In this case, no noise component arises and therefore, a pixel signal reading circuit in which the reset voltage of the FD node is boosted and a wide range of the output voltage is secured can be realized without deterioration in image quality even during operation at low power supply voltage.

By calculating a difference between the sampled reset voltage and signal voltage, fixed pattern noise caused by fluctuations in threshold of amplifier transistor 17 can be removed. Though a noise component caused by fluctuations of the transistor or the like arises in the reset voltage, such a noise component is fixed over time and thus, a similar noise component also arises in the signal voltage.

Therefore, a signal component from which fixed pattern noise is removed can be obtained calculating a difference between the reset voltage and signal voltage (double correlation sampling processing).

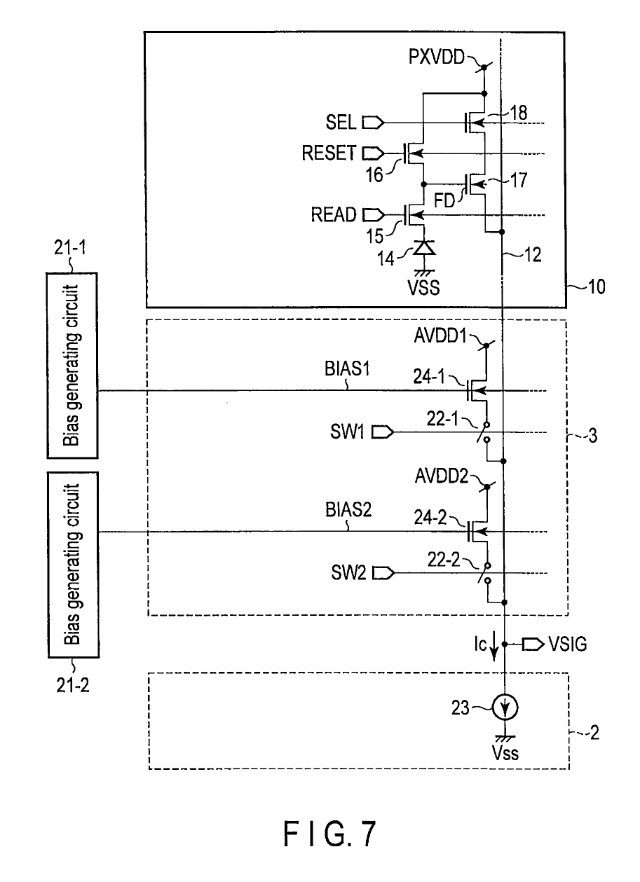

FIG. 7 is a diagram showing the second embodiment of the pixel signal reading circuit.

The present embodiment is different from the first embodiment in the configuration of voltage control portion 3 and otherwise, both embodiments are the same.

More specifically, voltage control portion 3 includes control transistors 24-1, 24-2 whose gate is connected to bias lines BIAS1, BIAS2 and switches 22-1, 22-2 that controls the short circuit/disconnection between the source of control transistors 24-1, 24-2 and vertical signal line 12. The drains of control transistors 24-1, 24-2 are connected to power nodes of voltage control portion 3 that controls the voltage of an output signal line, that is, control portion-power nodes AVDD1, AVDD2.

Switches 22-1, 22-2 may be connected to between control portion-power nodes AVDD1, AVDD2 and the drains of control transistors 24-1, 24-2.

Control portion-power nodes AVDD1, AVDD2 may be the same or different. If both are different, voltage Vadd1 of control portion-power node AVDD1 and voltage Vadd2 of control portion-power node AVDD2 may be the same or different.

Pixel-power node PXVDD and control portion-power node AVDD1 may be the same or different. If both are different, voltage Vdd of pixel-power node PXVDD and voltage Vdda1 of control portion-power node AVDD1 may be the same or different.

Pixel-power node PXVDD and control portion-power node AVDD2 may be the same or different. If both are different, voltage Vdd of pixel-power node PXVDD and voltage Vdda2 of control portion-power node AVDD2 may be the same or different.

Bias generating circuits 21-1, 21-2 supply a bias voltage to bias lines BIAS1, BIAS2 inside voltage control portion 3.

In the present embodiment, load circuit 2, amplifier transistor 17, and row select transistor 18 constitute a source follower circuit. Further, load circuit 2, switches 22-1, 22-2, and control transistors 24-1, 24-2 constitute a source follower circuit.

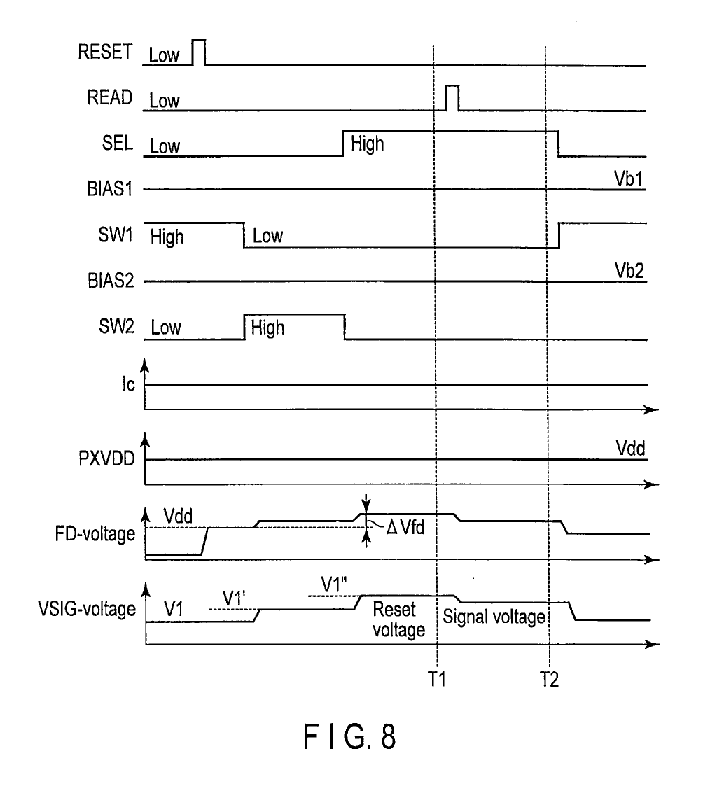

FIG. 8 is a timing chart when a pixel signal of the circuit in FIG. 7 is read.

When a pixel signal is read, switch 22-1 inside voltage control portion 3 is first turned on and vertical signal line 12 is set to predetermined voltage value V1. At this point, switch 22-2 inside voltage control portion 3 and row select transistor 18 are off and thus, a source follower circuit by load circuit (current source 23) 2, switch 22-1, and control transistor 24-1 functions.

In this state, reset transistor 16 is turned on and off, so the FD node is set to pixel power supply voltage Vdd of pixel-power node PXVDD.

Next, switch 22-1 inside voltage control portion 3 is turned off and switch 22-2 is turned on and vertical signal line 12 is set to predetermined voltage value V1′. At this point, switch 22-1 inside voltage control portion 3 and row select transistor 18 are off and thus, a source follower circuit by load circuit (current source 23) 2, switch 22-2, and control transistor 24-2 functions.

Then, row select transistor 18 inside pixel cell 10 is turned on and switch 22-2 inside voltage control portion 3 is turned off. At this point, with load circuit 2, amplifier transistor 17, and row select transistor 18, a source follower circuit functions.

At this point, Vb1, Vb2, Vthb1, Vthb2, Wb1, Wb2, Lb1, and Lb2 are set so that V1<V1′<V1″ holds for voltage V1″ of vertical signal line 12.

Vb1 is the bias voltage value generated by bias generating circuit 21-1, Vb2 is the bias voltage value generated by bias generating circuit 21-2, Vthb1 is the threshold voltage of control transistor 24-1 inside voltage control portion 3, Vthb2 is the threshold voltage of control transistor 24-2 inside voltage control portion 3, Wb1 and Lb1 are the gate width and gate length of control transistor 24-1 inside voltage control portion 3 respectively, and Wb2 and Lb2 are the gate width and gate length of control transistor 24-2 inside voltage control portion 3 respectively.

Then, with a rising voltage of vertical signal line 12 from V1 to V1′ and further from V1′ to V1″, the voltage of the FD node rises by being linked to a rise in output voltage. This is because, as shown in FIG. 4, the FD node and vertical signal line 12 are mutually capacity-coupled due to capacity Cgs between the gate and source of amplifier transistor 17.

The subsequent operation is the same as that in the first embodiment and a description thereof is omitted.

The foregoing is a pixel signal reading sequence in the second embodiment.

Also in the second embodiment, current source 23, which is load circuit 2, continues to pass a constant current during operation of pixel signal reading.

Thus, a phenomenon in which a current begins to flow abruptly due to a rise in reset voltage or the like does not occur.

Therefore, the reset voltage and signal voltage can be sampled without causing instability of voltages of pixel-power node PXVDD, FD node, and vertical signal line 12. In this case, no noise component arises and therefore, image quality does not deteriorate.

Thus, by performing a pixel signal reading operation according to the timing chart in FIG. 8, the FD node can be boosted to increase the reset voltage output to vertical signal line 12. As a result, a wide range of the output voltage can be secured without deterioration in image quality even during operation at low power supply voltage.

The second embodiment is different from the first embodiment in that the voltage of vertical signal line 12 stepwise rises from V1 to V1′ and further from V1′ to V1″. Accordingly, the voltage of the FD node is stepwise increased.

According to the second embodiment, the final reset voltage can be obtained after rises in voltage.

Therefore, an overshoot in a boost of the FD node can decreases when compared with the first embodiment in which the final reset voltage is obtained by one rise in voltage.

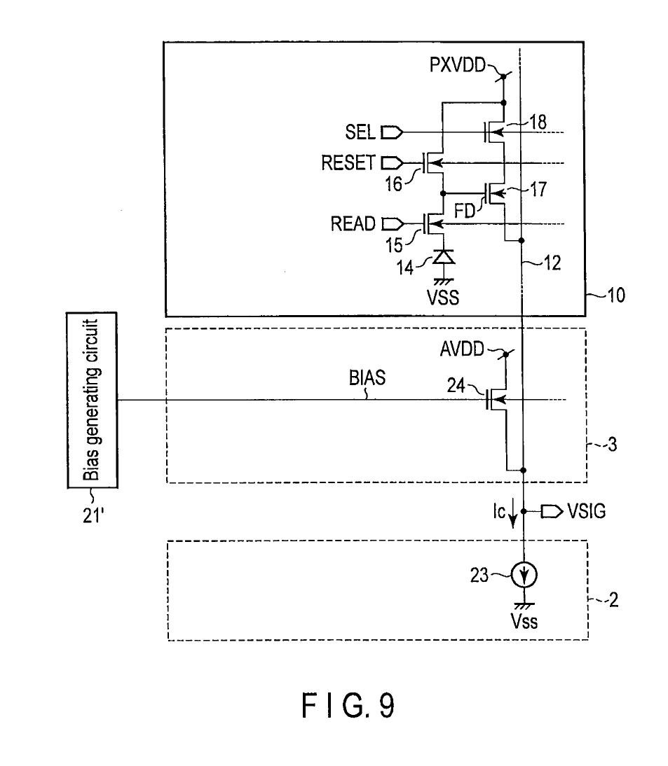

FIG. 9 is a diagram showing the third embodiment of the pixel signal reading circuit.

The present embodiment is different from the first embodiment in the configuration of voltage control portion 3 and otherwise, both embodiments are the same.

More specifically, voltage control portion 3 includes control transistor 24 whose gate is connected to bias line BIAS. The drain of control transistor 24 is connected to control portion-power node AVDD. In the present embodiment, the switch inside voltage control portion 3 present in the first embodiment is not present.

Pixel-power node PXVDD and control portion-power node AVDD may be the same or different. If both are different, voltage Vdd of pixel-power node PXVDD and voltage Vdda of control portion-power node AVDD may be the same or different.

Bias generating circuit 21′ supplies a bias voltage to bias line BIAS inside voltage control portion 3. The bias voltage is variable to control On/Off of control transistor 24.

In the present embodiment, load circuit 2, amplifier transistor 17, and row select transistor 18 constitute a source follower circuit. Further, load circuit 2 and control transistor 24 constitute a source follower circuit. On/Off of the source follower circuit constituted of load circuit 2 and control transistor 24 is controlled by bias generating circuit 21′.

That is, there is no switch inside voltage control portion 3, but bias generating circuit 21′ is configured to contain a switch (not shown).

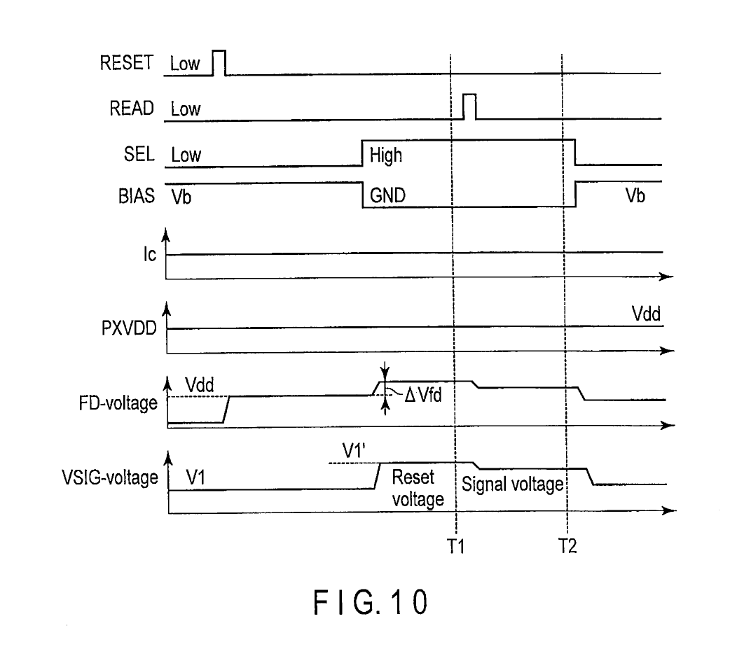

FIG. 10 is a timing chart when a pixel signal of the circuit in FIG. 9 is read.

When a pixel signal is read, a bias voltage generated by bias circuit 21′ is first set to Vb, control transistor 24 is turned on, and vertical signal line 12 is set to predetermined voltage value V1. At this point, row select transistor 18 is off and thus, a source follower circuit by load circuit (current source 23) 2 and control transistor 24 functions.

In this state, reset transistor 16 is turned on and off, so the FD node is set to pixel power supply voltage Vdd of pixel-power node PXVDD.

Then, row select transistor 18 inside pixel cell 10 is turned on, the output voltage of bias circuit 21′ is set to Vss (for example, the ground potential), and control transistor 24 is turned off. At this point, with load circuit 2, amplifier transistor 17, and row select transistor 18, a source follower circuit functions.

At this point, Vb, Vthb, Wb, and Lb are set so that V1<V1′ holds for voltage V1′ of vertical signal line 12.

Vb is the bias voltage value generated by bias generating circuit 21′, Vthb is the threshold voltage of control transistor 24 inside voltage control portion 3, and Wb and Lb are the gate width and gate length of control transistor 24 inside voltage control portion 3 respectively.

Then, with a rising voltage of vertical signal line 12 from V1 to V1′, the voltage of the FD node rises by being linked to a rise in output voltage. This is because the FD node and vertical signal line 12 are mutually capacity-coupled due to capacity Cgs between the gate and source of amplifier transistor 17.

The subsequent operation is the same as that in the first embodiment and a description thereof is omitted.

The foregoing is a pixel signal reading sequence in the third embodiment.

Also in the third embodiment, current source 23, which is load circuit 2, continues to pass a constant current during operation of pixel signal reading. Thus, a phenomenon in which a current begins to flow abruptly due to a rise in reset voltage or the like does not occur.

Therefore, the reset voltage and signal voltage can be sampled without causing instability of voltages of pixel-power node PXVDD, FD node, and vertical signal line 12. In this case, no noise component arises and therefore, image quality does not deteriorate.

Thus, by performing a pixel signal reading operation according to the timing chart in FIG. 10, the FD node can be boosted to increase the reset voltage output to vertical signal line 12. As a result, a wide range of the output voltage can be secured without deterioration in image quality even during operation at low power supply voltage.

The third embodiment is different from the first embodiment in that On/Off of a source follower circuit constituted of load circuit (current source 23) 2 and control transistor 24 is controlled by an output voltage of bias generating circuit 21′ without using a switch. Accordingly, the number of elements can be reduced.

According to the third embodiment, the number of elements can be reduced and therefore, the layout of peripheral circuits of a solid state imaging device is made easier and also a contribution to the reduction of the chip size can be made.

According to the embodiments, the reset voltage can be boosted without controlling the load circuit and therefore, the reset voltage can be boosted without deterioration in image quality even during operation at low power supply voltage.

The embodiments are particularly effective in applying to a pixel signal reading circuit of a CMOS image sensor.

In the embodiments, read transistor 15, reset transistor 16, amplifier transistor 17, and row select transistor 18 are constituted of an N—channel FET (field effect transistor) in pixel cell 10, but may also be constituted of a P-channel FET or other transistors than FET.

Similarly, in voltage control portion 3, control transistors 24, 24-1, 24-2 are constituted of an N-channel FET, but may also be constituted of a P-channel FET or other transistors than FET. Switches 22, 22-1, 22-2 can be constituted of, for example, the FET.

Photodiode 14 may be an N-type photodiode or a P-type photodiode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or Modifications as would fall within the scope and spirit of the inventions.

What is claimed is:

1. A solid state imaging device comprising:
a pixel cell including an FD node to convert a charge stored in a photodiode into a signal voltage and an amplifier transistor in which a gate is connected to the FD node, a source is connected to an output signal line, and a drain is connected to a pixel-power node;
a voltage control portion including a first control transistor in which a gate sets to a first bias voltage, a source is connected to the output signal line, and a drain is connected to a first control portion-power node;
a load circuit including a current source connected directly between one end of the output signal line and a source power supply node; and
a control circuit which controls an operation to decide a reset voltage of the output signal line,
wherein the control circuit boosts the FD node by activating a first source follower circuit comprising the first control transistor and the current source before activating a second source follower circuit comprising the amplifier transistor and the current source, and sets a voltage of the output signal line when the FD node is boosted as the reset voltage.

2. The device of claim 1,
wherein the load circuit has no switch function.

3. The device of claim 1,
wherein the load circuit continues to pass a constant current during operation of pixel signal reading.

4. The device of claim 1,
wherein the voltage control portion further includes a first switch to control the first source follower circuit.

5. The device of claim 1,
wherein the voltage control portion further comprises:
a first switch to control the first source follower circuit,
a second control transistor in which a gate sets to a second bias voltage, a source is connected to the output signal line, and a drain is connected to a second control portion-power node, and
a second switch which controls a third source follower circuit comprising the second control transistor and the current source,
wherein the control circuit causes the third source follower circuit after activating the first source follower circuit and before activating the second source follower circuit.

6. The device of claim 1,
wherein the first bias voltage is variable and
the first source follower circuit is controlled by On/Off of the first control transistor.

7. The device of claim 1,
wherein the control circuit reads the signal voltage to the output signal line by transferring the charge stored in the photodiode to the FD node after sampling the reset voltage in a sample hold circuit in an AD converter,
wherein the AD converter outputs a difference between the reset voltage and the signal voltage.

8. The device of claim 1, further comprising a read transistor connected to between the photodiode and the FD node.

9. The device of claim 1, further comprising a reset transistor connected to between the FD node and the pixel-power node to reset the voltage of the FD node.

10. The device of claim 1, further comprising a row select transistor connected to between the drain of the amplifier transistor and the pixel-power node.
